(19) United States
(12) Patent Application Publication
(10) Pub. No.: US 2025/0141387 A1
(43) Pub. Date: May 1, 2025

(54) POWER TOOL INCLUDING POWER LIMITING MOTOR CONTROL

(71) Applicant: MILWAUKEE ELECTRIC TOOL CORPORATION, Brookfield, WI (US)

(72) Inventors: Jacob G. Wood, Waukesha, WI (US); John M. Q. Van Treeck, Lannon, WI (US); Daniel R. Ertl, Kewaskum, WI (US); Benjamin D. Andersen, Menomonee Falls, WI (US)

(21) Appl. No.: 18/782,765

(22) Filed: Jul. 24, 2024

Related U.S. Application Data
(60) Provisional application No. 63/639,949, filed on Apr. 29, 2024.
(60) Provisional application No. 63/595,076, filed on Nov. 1, 2023.

(51) Int. Cl. H02P 27/08; G01R 31/3842; H02K 7/14; H02P 23/14

(52) U.S. Cl. CPC H02P 27/08; H02K 7/145; H02P 23/14; G01R 31/3842

(57) ABSTRACT

Power tools described herein include an electric motor, an interface configured to receive a battery pack, and an electronic controller. The electronic controller is configured to monitor a current value between the battery pack and the electric motor, monitor a voltage value between the battery pack and the electric motor, compute a power value based on the current value and the voltage value, and reduce an input power of the electric motor in response to the power value exceeding a threshold.

### RELATED APPLICATIONS

This application claims the benefit of U.S. Provisional Patent Application No. 63/595,076, filed Nov. 1, 2023, and U.S. Provisional Patent Application No. 63/639,949, filed Apr. 29, 2024, the entire content of each of which is hereby incorporated by reference.

### FIELD

This disclosure relates to power tools and, more particularly, to battery pack powered tools.

### SUMMARY

Using a common interface format for power tool battery packs brings a variety of technical and practical benefits. For example, users may be able to easily swap battery packs between different tools without needing to have specific battery packs for each tool. If a battery pack fails or runs out of charge, the battery pack can be quickly swapped with another battery pack, such as, from a different tool. Having a common interface format also allows different battery packs from different tools to be charged on the same charger. These improvements to interoperability greatly improve the flexibility of a power tool system. However, different battery packs may have different capabilities. These differences in capability may result from differences in design, or may result from the natural degradation of the battery cell chemistry or performance over time.

The internal impedance of a power tool battery pack can vary due to a variety of factors. For example, different battery cell chemistries may result in battery packs having different impedances. Typically, battery packs having lithium-ion (Li-ion) cells may have lower impedances than otherwise-similar battery packs having nickel-cadmium (Ni—Cd) or nickel metal hydride (NiMH) cells. Additionally, the construction and design of the battery pack may affect its impedance. For example, the quality and/or thickness of the materials used, the design of the electrodes, and/or the arrangement of the battery cells may affect the battery pack's impedance. Furthermore, as battery packs age and undergo more charge/discharge cycles, their internal structures may naturally degrade, which can result in impedance increases for the battery pack.

Generally, the impedance of a battery pack may be described as its opposition to the flow of alternating current (AC) or direct current (DC). Thus, the impedance of a battery pack may affect its power delivery. For example, battery packs with higher impedances may tend to deliver less power than battery packs having lower impedances. For power tools that have a common interface format and are capable of accepting a variety of different battery packs of different impedances, it can be technically challenging to ensure that the power tool motor produces a consistent power output. To solve these challenges, techniques described herein dynamically control the power provided to power tool motors, ensuring that the motors remain within optimal operating parameters when driven by any number of different battery packs of different impedances.

Power tools described herein include an electric motor, an interface configured to receive a battery pack, and an electronic controller. The electronic controller is configured to monitor a current value between the battery pack and the electric motor, monitor a voltage value between the battery pack and the electric motor, compute a power value based on the current value and the voltage value, and reduce an input power of the electric motor in response to the power value exceeding a threshold.

In some aspects, the current value is at least one of an inverter current value, a motor phase current value, and a battery current value. In some aspects, the voltage value is at least one of an inverter voltage value, a motor phase voltage value, and a battery voltage value. In some aspects, the electronic controller is configured to compute the power value based on the current value, the voltage value, and a duty cycle of the electric motor. In some aspects, the current value is a current value measured during an ON portion of a pulse width modulation signal. In some aspects, the power value is a time-averaged power value. In some aspects, the electronic controller is configured to compute the power value by providing the time-averaged power value to a filter. In some aspects, the filter is an infinite-impulse-response filter. In some aspects, the power value is a root mean square value. In some aspects, the electronic controller is configured to reduce the input power of the electric motor by reducing a requested pulse-width-modulation (PWM) value of the electric motor.

In some aspects, the threshold is a first threshold. The electronic controller is configured to stop reducing the input power of the electric motor in response to the power value falling below a second threshold, the second threshold lower than the first threshold. In some aspects, the power tool includes a spring-mass system driven by the electric motor. In some aspects, the spring-mass system includes a hammer configured to strike an anvil and a spring configured to bias the hammer toward the anvil.

Methods described herein for controlling an electric motor of a power tool include monitoring a current value between a battery pack and the electric motor, monitoring a voltage value between the battery pack and the electric motor, computing a power value based on the current value and the voltage value, and reducing an input power of the electric motor in response to the power value exceeding a threshold.

In some aspects, the current value is at least one of an inverter current value, a motor phase current value, and a battery current value. In some aspects, the voltage value is at least one of an inverter voltage value, a motor phase voltage value, and a battery voltage value. In some aspects, the power value is computed based on the current value, the voltage value, and a duty cycle of the electric motor. In some aspects, the current value is a current value measured during an ON portion of a pulse width modulation signal. In some aspects, the power value is a time-averaged power value. In some aspects, computing the power value includes providing the time-averaged power value to a filter. In some aspects, the power value is a root mean square value. In some aspects, the filter is an infinite-impulse-response filter. In some aspects, reducing the input power of the electric motor includes reducing a requested pulse-width-modulation (PWM) value of the electric motor.

In some aspects, the threshold is a first threshold, and the method includes stopping the reducing of the input power of the electric motor in response to the power value falling below a second threshold, the second threshold lower than the first threshold. In some aspects, the electric motor is configured to drive a spring-mass system. In some aspects, the spring-mass system includes a hammer configured to strike an anvil and a spring configured to bias the hammer toward the anvil.

Power tools described herein include an electric motor, an interface configured to receive a battery pack, and an electronic controller. The electronic controller is configured to monitor a current value between the battery pack and the electric motor, monitor a voltage value between the battery pack and the electric motor, compute a power value based on the current value and the voltage value, and reduce, in response to the power value reaching a threshold value, an input power of the electric motor.

Power tools described herein include an electric motor and an electronic controller. The electronic controller is configured to monitor a current value associated with the electric motor, monitor a speed value associated with the electric motor, compute an effort value based on the current value and the speed value, and reduce an effort of the electric motor in response to the effort value exceeding a threshold.

In some aspects, the electronic controller is configured to compute the effort value by multiplying the current value and the speed value. In some aspects, the electronic controller is configured to reduce the effort of the electric motor by reducing a duty cycle of the electric motor. In some aspects, the electronic controller is configured to reduce the effort of the electric motor by reducing a current supplied to the electric motor. In some aspects, the electronic controller is configured to reduce the effort of the electric motor by reducing a voltage supplied to the electric motor. In some aspects, the electronic controller is configured to reduce the effort of the electric motor by reducing a quadrature-axis current of the electric motor.

In some aspects, the electronic controller is configured to reduce the effort of the electric motor by receiving a commanded quadrature-axis current, receiving a maximum allowed quadrature-axis current, setting a value of the commanded quadrature-axis current to the maximum allowed quadrature-axis current in response to the commanded quadrature-axis current exceeding the maximum allowed quadrature-axis current, and computing a drive signal for the electric motor based on the value of the commanded quadrature-axis current. In some aspects, the electronic controller monitors the speed value of the electric motor by monitoring signals from one or more sensors at the electric motor. In some aspects, the electronic controller monitors the speed value by computing a rotational speed of the electric motor using a sensorless algorithm. In some aspects, the speed value is a rotational speed of the electric motor.

Methods described herein for controlling an electric motor of a power tool include monitoring a current value associated with the electric motor, monitoring a speed value associated with the electric motor, computing an effort value based on the current value and the speed value, and reducing an effort of the electric motor in response to the effort value exceeding a threshold.

In some aspects, computing the effort value based on the current value and the speed value includes multiplying the current value and the speed value. In some aspects, reducing the effort of the electric motor includes reducing a duty cycle of the electric motor. In some aspects, reducing the effort of the electric motor includes reducing a current supplied to the electric motor. In some aspects, reducing the effort of the electric motor includes reducing a voltage supplied to the electric motor. In some aspects, reducing the effort of the electric motor includes reducing a quadrature-axis current of the electric motor.

In some aspects, reducing the effort of the electric motor includes receiving a commanded quadrature-axis current, receiving a maximum allowed quadrature-axis current, setting a value of the commanded quadrature-axis current to the maximum allowed quadrature-axis current in response to the commanded quadrature-axis current exceeding the maximum allowed quadrature-axis current, and computing a drive signal for the electric motor based on the value of the commanded quadrature-axis current. In some aspects, monitoring the speed value associated with the electric motor includes monitoring signals from one or more sensors at the electric motor. In some aspects, monitoring the speed value associated with the electric motor includes computing a rotational speed of the electric motor using a sensorless algorithm. In some aspects, the speed value is a rotational speed of the electric motor.

Before any embodiments are explained in detail, it is to be understood that the embodiments are not limited in application to the details of the configurations and arrangements of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

Unless the context of their usage unambiguously indicates otherwise, the articles “a,” “an,” and “the” should not be interpreted as meaning “one” or “only one.” Rather these articles should be interpreted as meaning “at least one” or “one or more.” Likewise, when the terms “the” or “said” are used to refer to a noun previously introduced by the indefinite article “a” or “an,” “the” and “said” mean “at least one” or “one or more” unless the usage unambiguously indicates otherwise.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Accordingly, in the claims, if an apparatus, method, or system is claimed, for example, as including a controller, control unit, electronic processor, computing device, logic element, module, memory module, communication channel or network, or other element configured in a certain manner, for example, to perform multiple functions, the claim or claim element should be interpreted as meaning one or more of such elements where any one of the one or more elements is configured as claimed, for example, to make any one or more of the recited multiple functions, such that the one or more elements, as a set, perform the multiple functions collectively.

Other examples, embodiments, features, and aspects will become apparent by consideration of the detailed description and accompanying drawings.

### BRIEF DESCRIPTION OF THE DRAWINGS

FIG. 1 is an isometric view of a power tool, according to some embodiments.

FIG. 2 is a cross-sectional view of the power tool of FIG. 1 taken along section line 2-2, according to some embodiments.

FIG. 3A is an isometric view of an example battery pack for use with the power tool of FIGS. 1 and 2, according to some embodiments.

FIG. 3B is a schematic diagram illustrating a group of battery cells, according to some embodiments.

FIG. 4A is an isometric view of an example battery pack for use with the power tool of FIGS. 1 and 2, according to some embodiments.

FIG. 4B is a cross-sectional view of the battery pack of FIG. 4A taken along section line 4-4, according to some embodiments.

FIG. 5 is a block diagram illustrating an example control system for the power tool of FIGS. 1-2, according to some embodiments.

FIG. 6 is a flowchart of an example process for controlling operation of the power tool of FIGS. 1-2, according to some embodiments.

FIG. 7 is a block diagram illustrating a control loop that may be used to implement control schemes according to the process of FIG. 6, according to some embodiments.

FIG. 8 is a flowchart of an example process for controlling operation of the power tool of FIGS. 1-2, according to some embodiments.

FIG. 9 is a block diagram illustrating a control loop that may be used to implement control schemes according to the process of FIG. 8, according to some embodiments.

FIG. 10 is a block diagram illustrating a control loop 1000 that may be used to implement control schemes according to the process of FIG. 8, according to some embodiments.

In the drawings, reference numbers may be reused to identify similar and/or identical elements.

### DETAILED DESCRIPTION

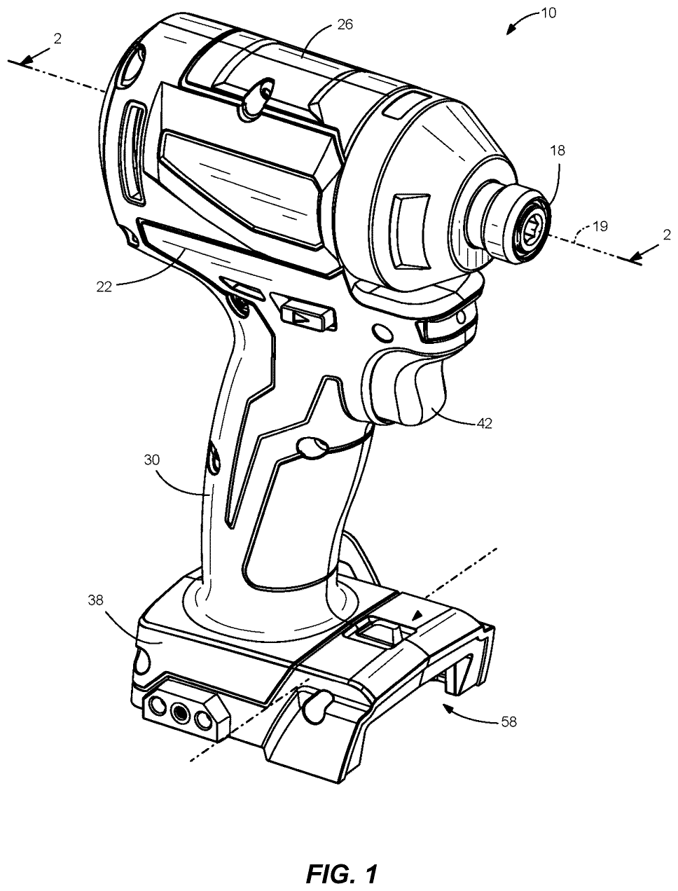

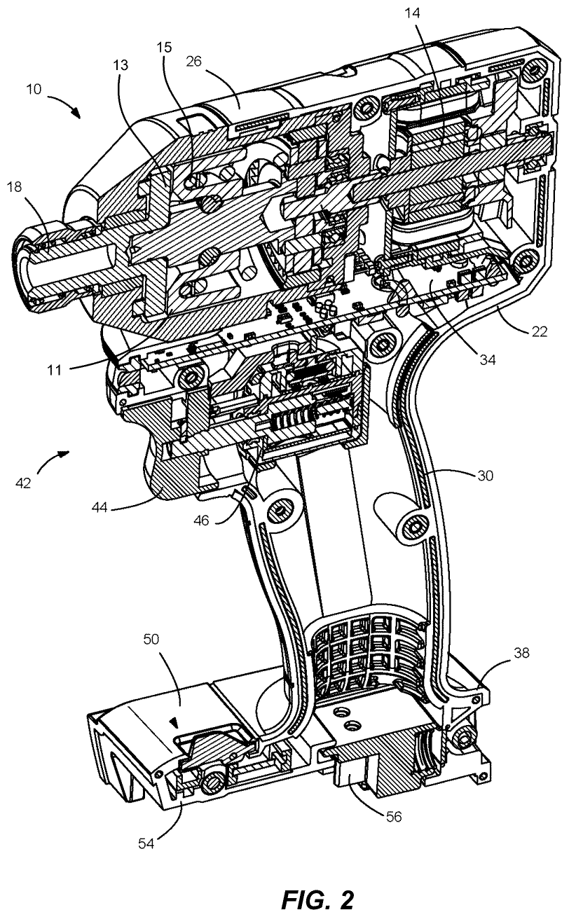

FIG. 1 is an isometric view of an example power tool 10. FIG. 2 is a cross-sectional view of the power tool 10 of FIG. 1 taken along section line 2-2. With reference to FIGS. 1 and 2 collectively, various implementations of the power tool 10 include an electric motor 14 and an output shaft 18 that receives torque from the electric motor 14. The output torque causes the output shaft 18 to rotate along an axis 19. In some embodiments, the electric motor 14 is a brushless direct current (“DC”) electric motor. In some examples, the power tool 10 may be a rotary power tool, such as an impact driver. In examples where the power tool 10 is configured as an impact driver, the power tool 10 delivers rotational force (e.g., torque) along with concussive blows (e.g., impacts) via the output shaft 18 (e.g., to assist in driving, loosening, and/or tightening fasteners).

In the impact driver configuration, some examples of the power tool 10 may include a non-linear spring-mass system, such as a hammer-and-anvil mechanism. In various implementations, the hammer-and-anvil mechanism includes a hammer 11 rotationally driven by the electric motor 14, an anvil 13 coupled to the output shaft 18 that drives the output shaft 18 in a rotational manner, and a spring 15 biasing the hammer 11 towards the anvil 13. A side of the hammer 11 facing the anvil 13 may include a first cam profile, and a side of the anvil facing the hammer 11 may include a second cam profile. The first cam profile may engage with the second cam profile so that the rotational motion of the hammer 11 causes the anvil 13 to rotate in the same direction. When the output shaft 18 is rotating against a relatively lower amount of resistance torque (e.g., below a resistance torque threshold), the spring force that spring 15 exerts on hammer 11 is sufficient to keep the first cam profile engaged with the second cam profile (and the hammer 11 coupled to the anvil 13).

However, when the output shaft 18 is rotating against a relatively higher amount of resistance torque (e.g., above the resistance torque threshold), the camming interaction between the first cam profile of the hammer 11 and the second cam profile of the anvil 13 overcomes the spring force exerted by the spring 15 on the hammer 11, which allows the hammer 11 to begin moving away from the anvil 13. Once the hammer 11 has moved a sufficient distance away from the anvil 13, the camming interaction between the first cam profile of the hammer 11 and the second cam profile of the anvil 13 allows the cams of the hammer 11 to slip past the cams of the anvil 13, which cause the compressed spring 15 to release its energy and propel the hammer 11 forward towards and strike the anvil 13. During this process, the electric motor 14 continues rotating the hammer 11, and the cams of the hammer 11 re-engage with the cams of the anvil 13, applying a torque impulse to the anvil 13. This torque impulse may overcome the resistance torque encountered at the output shaft 18, allowing the output shaft 18 to drive or loosen fasteners requiring more torque than the electric motor 14 may be able to output.

In various implementations, the power tool 10 includes a housing 22 having a motor housing portion 26 in which the motor 14 is supported. In some embodiments, the handle portion 30 also includes a foot 38 continuous with an end of the handle portion 30 opposite the motor housing portion 26. The power tool 10 may also include a trigger unit 42 having an actuator portion 44 and an electromechanical switch portion 46. In some examples, the actuator portion 44 may be slidably received in an opening formed in the handle portion 30. The actuator portion 44 may be in contact with the electromechanical switch portion 46, and the electromechanical switch portion 46 may generate a signal according to a position of the actuator portion 44. The controller 34 may control the motor 14 according to the signal generated by the electromechanical switch portion 46, which may be varied according to the position of the actuator portion 44.

The foot 38 may include a top surface 50 and a bottom surface 54 opposite the top surface 50. The foot 38 may be configured to detachably receive a battery pack within a battery receptacle 58 defined in the bottom surface. The power tool 10 may include electrical conductors 56 in the foot 38 that mechanically and electrically connect the battery pack to the controller 34.

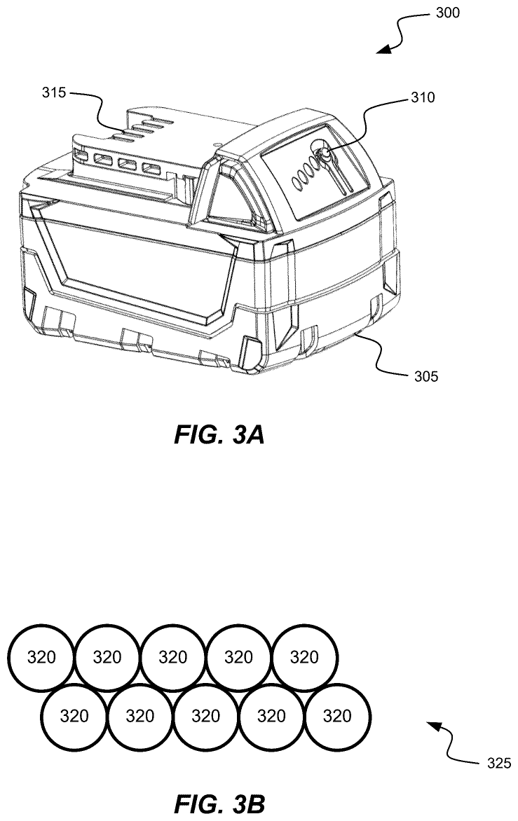

FIG. 3A is an isometric view of an example battery pack 300 for use with the power tool 10 of FIGS. 1 and 2. As illustrated in FIG. 3A, some implementations of the battery pack 300 include a housing 305, a user interface portion 310 for providing a state-of-charge indication for the battery pack 300, and a device interface portion 315 for connecting the battery pack 300 to the power tool 10. For example, the battery pack 300 may be electrically and mechanically connected to the power tool 10 via the electrical conductors of the battery receptacle 58 of the power tool 10. The battery pack 300 may include a plurality of battery cells within the housing 305.

FIG. 3B is a schematic diagram illustrating a group 325 of battery cells 320 that include, for example, ten individual battery cells 320. The battery cells 320 can be located within the housing 305 of the battery pack 300 and be electrically connected to the power tool 10 via the device interface portion 315. In various implementations, the battery pack 300 includes more than the 10 battery cells 320 shown in FIG. 3B. In some examples, the battery pack 300 includes fewer than the 10 battery cells 320 shown in FIG. 3B.

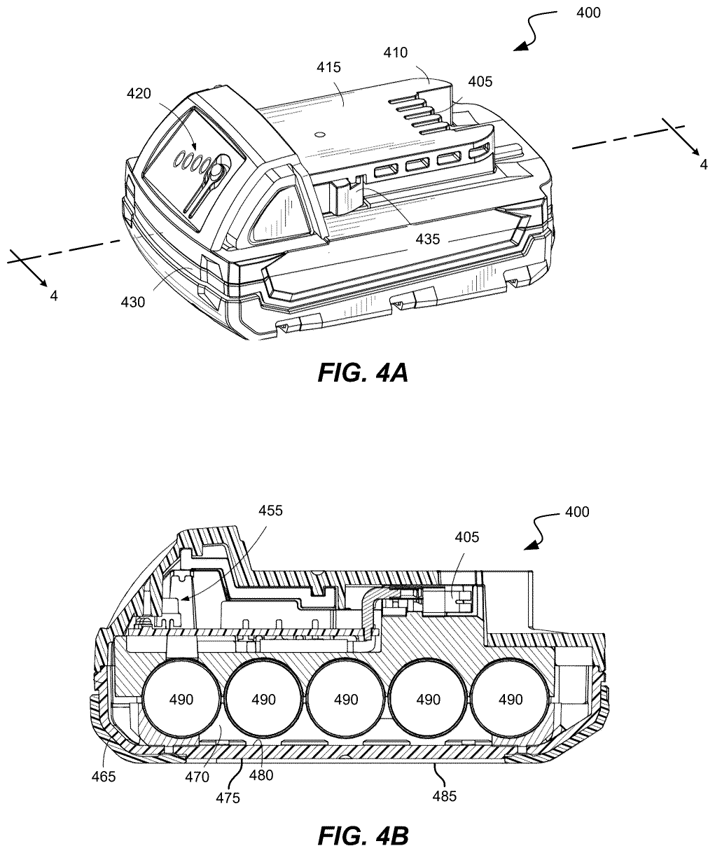

FIG. 4A is an isometric view of an example battery pack 400 for use with the power tool 10 of FIGS. 1 and 2. FIG. 4B is a cross-sectional view of the battery pack 400 of FIG. 4A taken along section line 4-4. As illustrated in FIGS. 4A-4B, the battery pack 400 may include a housing 430 and contain one or more battery cells. The housing 430 may include a wall 465 having an inside surface 480 and an outside surface 475. The inside surface 480 may define an internal cavity 470. The outside surface 475 may include a top surface portion 415 and a bottom portion 485. In various implementations, the battery cells 490 disposed within the cavity 470 are connected in series to battery contacts 405. A plurality of contacts 405 may be disposed on the top surface portion 415, for example, at a battery contacts housing extension 410. The housing extension 410 may be configured to matingly engage with one or more power tools or powered accessories. For example, the housing extension 410 may include one or more tabs 435 for releasably securing the housing 430 to the battery receptacle 58 of the power tool 10.

In various implementations, a battery charge level indicator 420 is disposed on the housing 430, and additional battery charging, monitoring, and indication components 455 may be disposed within the cavity 470. Corresponding features to those described above with reference to the battery pack 400 of FIGS. 4A-4B may be included in the battery pack 300 of FIGS. 3A-3B. It should be understood that battery packs 300 and 400 are provided as example illustrations of battery packs for use with power tool 10. However, battery packs for use with power tool 10 may take various sizes and shapes, include various numbers and types of battery cells, and/or include various numbers and types of tabs or other connection mechanisms for providing mechanical and/or electrical connections to the power tool 10. Additionally, it should be understood that battery packs for use with the power tool 10 may include additional or fewer components in various configurations. That is, the example battery packs 300 and 400 illustrated in FIGS. 3A-4B are not limiting.

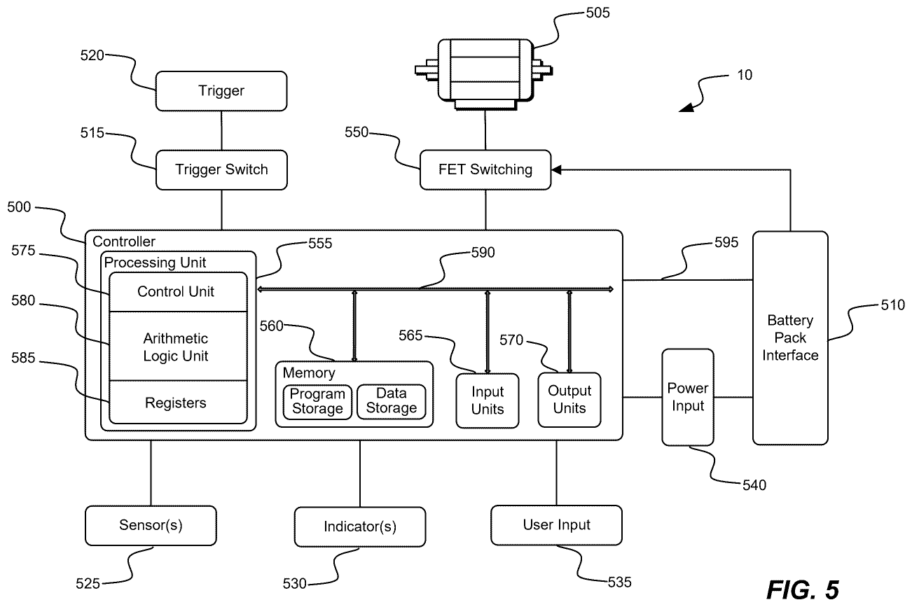

FIG. 5 is a block diagram illustrating an example control system for the power tool 10 of FIGS. 1-2. As illustrated in FIG. 5, the control system may include a controller 500. In various implementations, the controller 34 may be implemented according to the controller 500. The controller 500 may be electrically and/or communicatively connected to a variety of modules or components of the power tool 10. For example, the controller 500 may be electrically connected to a motor 505 (e.g., the electric motor 14), a battery pack interface 510 (e.g., the electrical conductors 56), a trigger switch 515 (e.g., the electromechanical switch portion 46) connected to a trigger 520 (e.g., the actuator portion 44), one or more sensors or sensing circuits 525, one or more indicators 530, a user input module 535, a power input module 540, and/or a field-effect transistor (FET) switching module 550. The controller 500 may include combinations of hardware and software that are operable to, among other things, control the operation of the power tool 10 (for example, by controlling the operation of the motor 505), monitor the operation of the power tool 10 (for example, by monitoring the operation of the motor 505), activate the one or more indicators 530 (e.g., controlling operation of one or more light-emitting diodes [LEDs], controlling outputs from one or more speakers, and/or controlling graphical outputs rendered on one or more displays), etc.

In various implementations, the controller 500 includes one or more electrical and electronic components that provide power, operational control, and/or protection to the components and/or modules within the controller 500 and/or power tool 10. For example, the controller 500 may include, among other things, a processing unit 555 (e.g., one or more microprocessors, microcontrollers, electronic processors, electronic controllers, and/or other suitable programmable devices), a memory 560, input units 565, and/or output units 570. In some embodiments, the processing unit 555 includes, among other things, a control unit 575, an arithmetic-logic unit (ALU) 580, and/or one or more registers 585 (shown as a group of registers in FIG. 5). The processing unit 555 may be implemented according to a known computer architecture (e.g., a Von Neumann architecture, a Harvard architecture, a reduced instruction set computing [RISC] architecture, a complex instruction set computing [CISC] architecture, a single instruction, multiple data [SIMD] architecture, a multiple instruction, multiple data [MIMD] architecture, and/or an explicitly parallel instruction computing [EPIC] architecture, etc.).

In various implementations, the processing unit 555, the memory 560, the input units 565, and/or the output units 570 (as well as the various modules and/or circuits connected to the controller 500) are connected by one or more control and/or data buses such as the common bus 590. In FIG. 5, the control and/or data buses are shown generally for illustrative purposes. The use of one or more control and/or data buses for the interconnection between and communication among the various modules, circuits, and/or components would be appreciated by a person of ordinary skill in the art in view of the disclosure of this specification. The memory 560 may include one or more non-transitory computer-readable storage media, which may be divided into, for example, a program storage area and/or a data storage area. In some embodiments, the program storage area and the data storage area include combinations of the same or different types of memory, such as read-only memory (ROM), random-access memory (RAM), electrically erasable read-only memory (EEROM), flash memory, hard drives, Secure Digital (SD) cards, and/or other suitable magnetic, optical, physical, and/or electronic memory devices.

The processing unit 555 may be connected to the memory 560 and executes software instructions stored in the memory 560 and/or software instructions stored on another non-transitory computer-readable storage medium, such as another memory. In various implementations, software (such as the control techniques described further on in this specification with reference to the flowcharts) for controlling the power tool 10 can be stored in the memory 560 of the controller 500. The software may include, for example, firmware, one or more applications, program data, filters, rules, one or more program modules, and/or other executable instructions. The controller 500 may be configured to retrieve the executable instructions from the memory 560 and execute, among other things, instructions related to the control processes and/or methods described herein. In other constructions, the controller 500 includes additional components. In some examples, the controller 500 includes fewer components. In various implementations, the controller 500 includes different components.

The battery pack interface 510 may include a combination of mechanical components (such as rails, grooves, and/or latches, etc.) and electrical components (such as one or more terminals and/or electrical conductors 56) configured to and operable for interfacing (e.g., mechanically, electrically, and, communicatively connecting) the power tool 10 with a battery pack (e.g., the battery pack 300 and/or the battery pack 400). For example, power from the battery pack 300 and/or 400 may be provided to the power tool 10 through the battery pack interface 510 to the power input module 540. The power input module 540 may include combinations of active and/or passive components to regulate and/or control the power received from the battery pack 300 and/or 400 prior to the power being provided to the controller 500. The battery pack interface 510 may also supply power to the FET switching module 550 to provide power to the motor 505. The battery pack interface 510 may also include, for example, a communication line 595 for providing a communication link between the control 500 and the battery pack 300 and/or 400.

The indicators 530 may include, for example, one or more LEDs. The indicators 530 may be configured to display conditions of or information associated with the power tool 10. For example, in some aspects, the indicators 530 are configured to indicate the measured electrical characteristics of the power tool 10, the status of the power tool 10, etc. The user input module 535 may be operably couple to the controller 500 to, for example, select a forward mode of operation or a reverse mode of operation, a torque, and/or a speed setting for the power tool 10. In various implementations, the user input module 535 may be used to select other operations of the power tool 10. In some embodiments, the user input module 535 includes one or more digital input devices, one or more digital output devices, one or more analog input devices, one or more analog output devices, or a combination, such as, for example, one or more knobs, one or more dials, one or more switches, and/or one or more buttons, etc. In various implementations, the user input module 535 includes a touchscreen usable as an input device, an output device, or a combination thereof.

In some aspects, the controller 500 is configured to determine whether a fault condition of the power tool 10 is present and generate one or more control signals related to the fault condition. For example, the sensing circuits 525 may include one or more current sensors, one or more voltage sensors, one or more speed sensors, one or more torque sensors, one or more Hall Effect sensors, one or more temperatures sensors, or combinations thereof. The controller 500 may be configured to process data received from the sensing circuits 525 to determine whether a fault condition is present. For example, the controller 500 may be configured to compare data received from the sensing circuits 525 (e.g., in a raw form, a processed form, or combinations thereof) to one or more predetermined operational threshold values and/or limits, which the controller 500 may calculate or access (e.g., from memory 560). For example, when a potential thermal failure (e.g., of a FET, the motor 505, etc.) is detected or predicted by the controller 500, the controller 500 may be configured to limit or interrupt power supplied to the motor 505 from the interfaced battery pack 300 and/or 400 until, for example, the potential for thermal failure is reduced, the power tool 10 is reset, etc. In some aspects, the controller 500 is configured to, in response to detecting one or more such fault conditions of the power tool 10 or determining that a fault condition of the power tool 10 is no longer present, provide information and/or control signals to another component of the power tool 10 (e.g., the indicators 530), the battery pack 300 and/or 400 (e.g., via the battery pack interface 510), or combinations thereof.

Various examples of the controller 500 may implement control techniques that provide a variety of technical improvements to a power tool. For example, the power tool 10 (e.g., an impact wrench) may include non-linear spring-mass systems (such as the hammer 11, anvil 13, and spring 15 previously described with reference to FIGS. 1-2) controlled by an electric motor 505. There may be an optimal output speed for the electric motor 505 to drive the non-linear spring-mass system for any given torque output setting to achieve optimal engagement between the hammer 11 and the anvil 13. If the output speed from the electric motor 505 is too high for the given torque output setting, the hammer 11 and the anvil 13 may engage in a sub-optimal manner by “crashing.” As previously discussed, however, reducing the impedance of the battery pack driving the motor 505 (for example, by replacing a degraded or older battery pack with a less-degraded or improved battery pack) may increase the output speed of the electric motor 505 for at the given torque setting. This may result in worse engagements and increased crashing between the hammer 11 and the anvil 13.

Control techniques described herein address these technical challenges by dynamically reducing the power output by the motor 505. For instance, the motor 505 may be configured to run at a specified output torque T. Since the mechanical power output P of the motor 505 may be defined as a function of the output torque T and the output angular velocity ω, equation (1) below, reducing the power output P of the motor 505 may also reduce the output angular velocity ω for any given output torque T, improving the engagement between the hammer 11 and the anvil 13.

$$P = T \cdot ω \qquad ( 1 )$$

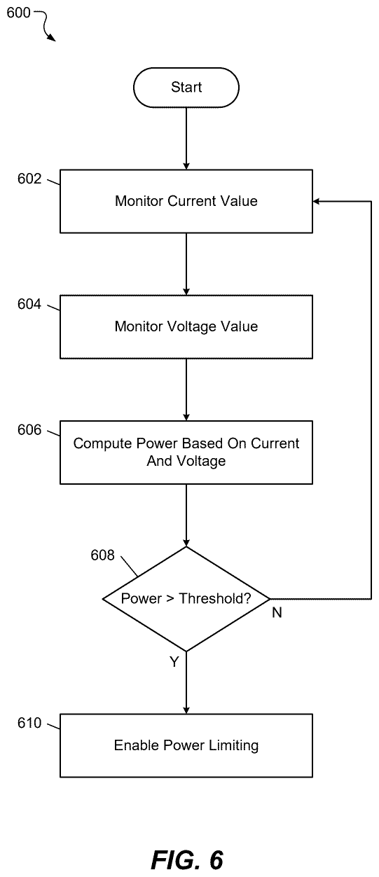

FIG. 6 is a flowchart of an example process 600 for controlling operation of the power tool 10 of FIGS. 1-2. At block 602, the controller 500 monitors a current value. In various implementations, the controller 500 monitors instantaneous current values taken at sensor(s) 525. In some examples, the controller 500 monitors average current values taken at sensor(s) 525. In some examples, the sensor(s) 525 measure a battery current (e.g., the electrical current flowing from the battery pack to the motor 505 during operation). For example, the sensor(s) 525 may measure current values between the battery pack interface 510 and the motor 505. In some embodiments, the sensor(s) 525 measure current values between the battery pack interface 510 and the FET switching module 550. In various implementations, the sensor(s) 525 measure an inverter current. For example, the sensor(s) 525 may measure current values between the FET switching module 550 and the motor 505. In some examples, the measured current may be the phase current of the motor 505. For example, the measured current may be an electrical current flowing through a phase in the windings of the motor 505.

In some examples, the motor 505 is a brushed DC motor, and the controller 500 monitors a steady-state current of the motor 505 measured by the sensor(s) 525. In various implementations, the motor 505 is a brushless DC (BLDC) motor (e.g., a BLDC motor utilizing pulse width modulation (PWM) control) and the controller 500 monitors an average current provided to the motor 505 (e.g., a mean value of the current measured by the sensor(s) 525 taken over a period of time). For example, the controller 500 monitors a current value when the PWM signal is in the “ON” phase and multiplies the current value with the duty cycle (e.g., the ratio of “ON” time to the total period of the PWM cycle) to determine an average current. The average current may provide an indication of the power being delivered to the motor 505. In various implementations, the controller 500 determines a root mean square (RMS) current provided to the motor 505.

In some embodiments, the measured current may be the quadrature-axis current (i_{q}) output from the FET switching module 550. In various implementations, the sensor(s) 525 measure torque outputs from the motor 505 instead of or in addition to current values. At block 604, the controller 500 monitors a voltage value. In various implementations, the controller 500 monitors instantaneous voltage values taken at sensor(s) 525. In some embodiments, the sensor(s) 525 measure a battery voltage (e.g., voltage values across two points between the battery pack interface 510 and the motor 505 and/or voltage values across two points between the battery pack interface 510 and the FET switching module 550). In various implementations, the sensor(s) 525 measure an inverter voltage (e.g., voltage values across two points between the FET switching module 550 and the motor 505). In some examples, the sensor(s) 525 measure a motor phase voltage (e.g., voltage values applied to a winding of the motor 505). In some examples, the controller 500 determines an average voltage based on the signals from the sensor(s) 525. In various implementations, the controller 500 determines an RMS voltage based on the signals from the sensor(s) 525. In some embodiments, the sensor(s) 525 measure speed outputs from the motor 505 instead of or in addition to voltage values.

At block 606, the controller 500 computes a power based on the measured current and the measured voltage. In some examples, the computed power may represent the electrical power provided to the motor 505 to drive the motor 505. For example, the controller 500 may compute the power based on the measured current value, the measured voltage value, a duty cycle value of the motor 505, and a requested power percentage value of the motor 505. In various implementations, the duty cycle value may be the ratio of “on” time to the total period of the PWM cycle commanded by the controller 500 expressed as a percentage or numerical value. In some examples, the requested power percentage value may be the percentage of the rated output power of the motor 505 requested by the controller 500. In some embodiments, the controller 500 computes the power by multiplying the measured current and the measured voltage.

In various implementations, the controller 500 computes a time-averaged power across a period of time (for example, by multiplying measured current, measured voltage, and the duty cycle value for the period of time). In some embodiments, the controller 500 determines a peak current value (iₚₑₐₖ) for the period of time, average voltage value (Vₐᵥₑ) for the period of time, and a duty cycle value for the period of time (D). In various implementations, the peak current value (iₚₑₐₖ) is a true peak value of the current. In other examples, the peak current value (iₚₑₐₖ) is not a true peak value of the current, but rather a current value measured during an “ON” phase of a PWM signal. In various implementations, the controller 500 calculates the time-averaged power (Pₐᵥₑ) according to equation (2) below:

$${P}_{ave} = {i}_{peak} \cdot {V}_{ave} \cdot D \qquad ( 2 )$$

In some examples, the controller 500 determines an average speed value (Kₐᵥₑ) for the period of time instead of the average voltage value (Vₐᵥₑ) and computes the time-averaged power (Pₐᵥₑ) according to equation (3) below:

$${P}_{ave} = {i}_{peak} \cdot {K}_{ave} \cdot D \qquad ( 3 )$$

In some embodiments, the controller 500 determines a peak torque value (Tₚₑₐₖ) for the period of time instead of the peak current value (iₚₑₐₖ) and computes the time-averaged power (Pₐᵥₑ) according to equation (4) below:

$${P}_{ave} = {T}_{peak} \cdot {V}_{ave} \cdot D \qquad ( 4 )$$

In various implementations, the controller 500 determines a peak torque value (Tₚₑₐₖ) for the period of time instead of the peak current value (iₚₑₐₖ) and an average speed value (Kₐᵥₑ) for the period of time instead of the average voltage value (Vₐᵥₑ) and computes the time-averaged power (Pₐᵥₑ) according to equation (5) below:

$${P}_{ave} = {T}_{peak} \cdot {K}_{ave} \cdot D \qquad ( 5 )$$

In various implementations, the controller 500 computes an RMS power based on the RMS current and the RMS voltage provided to the motor 505.

In some examples, the controller 500 computes a filtered power value. For example, the power value (such as the time-averaged power Pₐᵥₑ) may be provided to a filter, such as an infinite-impulse-response (“IIR”) filter. In various implementations, the filter may be an IIR filter having a length of seven. In some embodiments, the filter may be a 6th-ordered low-pass filter. The controller 500 compares the computed power (such as the filtered power value) to a threshold at decision block 608. In various implementations, the threshold may be fixed or adjusted dynamically. In some examples, the threshold may be adjusted dynamically according to known algorithms. In some embodiments, the threshold may be adjusted according to operating modes of the power tool 10 and/or control modes of the motor 505. In response to determining that the computed power is not over the threshold (“NO” at decision block 608), the process 600 returns to block 602. In response to determining that the computed power is over the threshold (“YES” at decision block 608), the controller 500 enables power limiting (for example, by reducing the power provided to the motor 505) at block 610.

In various implementations, the controller 500 may limit the power output by the motor 505 by reducing the duty cycle of the motor 505. In some examples, the controller 500 may limit the power output by the motor 505 by reducing the pulse-width of the PWM signal used to control the motor 505. In various implementations, the controller 500 may limit the power output by the motor 505 by reducing the conduction band of the signal used to drive the motor 505. In some embodiments, the controller 500 may limit the power output by the motor 505 by adjusting the advance angle of the control signal used to control the motor 505.

In various implementations, the motor 505 may be controlled according to block commutation and/or field oriented control (“FOC”). In some embodiments, the motor 505 is controlled using sensorless motor control (e.g., sensorless FOC). Power may be reduced by reducing the duty cycle, the magnitude of the voltage applied to the motor, and/or the current amplitude. In some examples, the power may be reduced by controlling the direct-axis current (i_{d}) and/or the quadrature-axis current (i_{q}) using FOC.

In some embodiments, after the controller 500 enables power limiting, the controller 500 continues monitoring current values, monitoring voltage values, and computing power based on the monitored current and voltage values. In response to the determining that the computed power is below a second threshold, the controller 500 disables power limiting (for example, by providing the full commanded power to the motor 505). In various implementations, the second threshold may be lower than the first threshold of decision block 608.

Various implementations of the process 600 provide a variety of technical benefits over other power tool control techniques. For example, as previously described, using battery packs with lower impedances may result in a higher output angular velocity from the motor 505 than when using battery packs with higher impedances (at the same torque setting). For some power tools, such as impact tools, this increase in output angular velocity from the motor 505 may result in increased crashing between the hammer 11 and the anvil 13 of the power tool 10. By preventing the power provided to the motor 505 from exceeding the threshold (e.g., in usage cases where lower impedance battery packs are used to drive the motor 505), the process 600 ensures that the output angular velocity of the motor 505 remains in an optimal range (e.g., to prevent crashing between the hammer 11 and the anvil 13) when a lower impedance battery pack is used with the power tool 10.

Furthermore, techniques implemented according to process 600 may compare a time-averaged power against the threshold. This filters out the inrush current when the trigger switch 515 is initially activated, reducing spurious power limiting by the controller 500 at the beginning of the operating cycle. Additionally, comparing a filtered power value to the threshold reduces the effects of rapid changes in the power as the spring-mass system formed by the hammer 11, anvil 13, and spring 15 oscillates between freely spinning (e.g., when the output shaft 18 encounters lower resistance torque) and when energy is stored in spring 15 (e.g., when the output shaft 18 encounters higher resistance torque). Moreover, disabling power limiting only after the computed power falls below the second threshold (which may be lower than the threshold) ensures that the power tool 10 does not frequently enter and exit power limiting in edge cases.

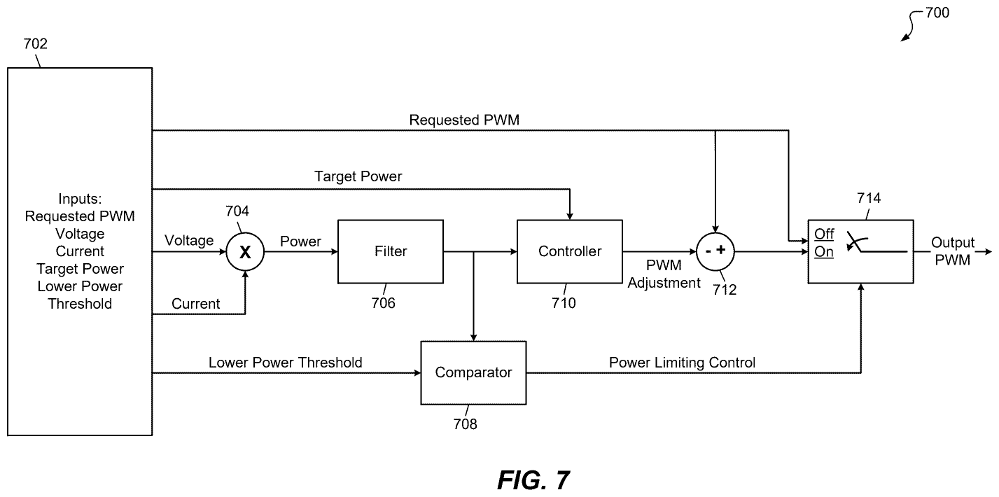

FIG. 7 is a block diagram illustrating a control loop 700 that may be used to implement control schemes according to the process 600 of FIG. 6. In various implementations, the control loop 700 may be implemented by the controller 500. As illustrated in FIG. 7, the inputs 702 to the control loop 700 may include a requested PWM for the motor 505, a voltage measurement of voltage provided to the motor 505, a current measurement of current provided to the motor 505, a target power for the motor 505 (such as the threshold previously described with reference to decision block 608 of process 600), and a lower power threshold (such as the second threshold previously described with reference to process 600). The voltage measurement, current measurement, and the duty cycle of the motor 505 are provided as inputs to a multiplier 704 to compute a power. In various implementations, the current measurement may be a peak current measurement. The computed power is provided to a filter 706 to generate a filtered power value. In various implementations, the filter 706 may be any of the filters previously described with reference to process 600.

The filtered power value and the target power value are provided as inputs to a controller 710. The controller 710 may be a bounded proportional and integral (“PI”) controller. In various implementations, the controller 710 may be a proportional-integral-derivative (“PID”) controller or other suitable controller. The controller 710 may compare the filtered power to a maximum power limit, which may be set in the firmware of the controller 710. As previously described, the maximum power limit may be static or dynamically adjusted. The output of the controller 710 may be an error between the filtered power value and the maximum power limit and may be bounded by the maximum output power and the minimum output power as a percentage value (e.g., between 0% and 100%). The error (e.g., a percentage of motor power) may be used to adjust the requested PWM at regulator 712. For example, if the filtered power input into the controller 710 is above the maximum power limit, the controller 710 outputs the error as a percentage value below 100%, and the regulator 712 reduces the requested PWM by the error to generate a reduced PWM.

Comparator 708 may selectively enable or disable power limiting by controlling switch 714. When power limiting is enabled, switch 714 provides the PWM signal (such as the reduced PWM) output from regulator 712 as the output PWM of the control loop 700. When power limiting is disabled, the switch 714 provides the requested PWM from inputs 702 as the output PWM of the control loop 700. In some embodiments, comparator 708 compares the filtered power output by filter 706 to a lower power threshold. In response to determining that the filtered power is greater than or equal to the lower power threshold, the comparator 708 outputs a power limiting control signal to enable power limiting control at switch 714 (e.g., to provide the output of the regulator 712 as the output PWM of the control loop 700). In some embodiments, the comparator 708 outputs a control signal to disable power limiting control at switch 714 (e.g., to provide the requested PWM from inputs 702 as the output PWM of the control loop 700).

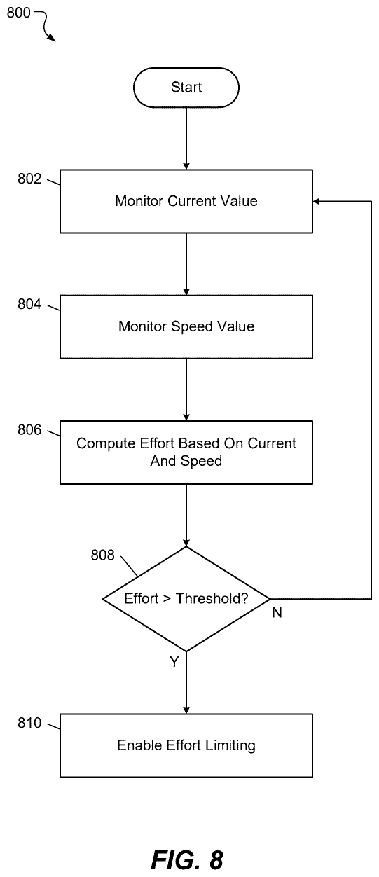

FIG. 8 is a flowchart of an example process 800 for controlling operation of the power tool 10 of FIGS. 1-2. At block 802, the controller 500 monitors a current value. In various implementations, the controller 500 monitors instantaneous current values taken at sensor(s) 525. In some examples, the controller 500 monitors average current values taken at sensor(s) 525. In various implementations, the sensor(s) 525 measure a battery current (e.g., the electrical current flowing from the battery pack to the motor 505 during operation). For example, the sensor(s) 525 may measure current values between the battery pack interface 510 and the FET switching module 550. In some examples, the sensor(s) 525 measure an inverter current. For example, the sensor(s) 525 may current values between the FET switching module 550 and the motor 505. In various implementations, the sensor(s) 525 measure current values at the motor 505. For example, the sensor(s) 525 measure a phase current of the motor 505 (e.g., an electric current that flows through one of the phases in the windings of the motor 505).

In some examples, the motor 505 is a brushed DC motor, and the controller 500 monitors a steady-state current of the motor 505 measured by the sensor(s) 525. In various implementations, the motor 505 is a brushless DC (BLDC) motor—for example, a BLDC motor utilizing pulse width modulation (PWM) control—and the controller 500 monitors an average current provided to the motor 505 (e.g., a mean value of the current measured by the sensor(s) 525 taken over a period of time). For example, the controller 500 monitors a current value when the PWM signal is in the “ON” phase and multiplies the current value with the duty cycle (e.g., the ratio of “ON” time to the total period of the PWM cycle) to determine the average current. The average current may provide an indication of the power being delivered to the motor 505. In some examples, the controller 500 determines an RMS current provided to the motor 505.

In various implementations, the motor 505 is a BLDC motor controlled according to field oriented control (FOC), and the controller 500 monitors a quadrature-axis current (i_{q}) and/or a direct-axis current (i_{d}) of motor 505. In examples where the motor 505 is controlled according to FOC, the controller 500 may decompose stationary phase currents (e.g., the three-phase currents [iₐ, i_{b}, and i_{c}]) into the quadrature-axis current (i_{q}) and/or the direct-axis current (i_{d}) using Clarke and Park transformations. For example, the three-phase currents (iₐ, i_{b}, and i_{c}) may be in the three-phase stationary reference frame, which may be tied to the stator of the motor and does not rotate. The controller 500 applies Clarke transformations to the three-phase currents (iₐ, i_{b}, and i_{c}), which transforms the currents from the stationary reference frame into two orthogonal components in a two-dimensional stationary α-β reference frame. In the α-β reference frame, the currents may be represented as i_{α} and i_{b}. The controller 500 may apply Park transformations to convert the i_{α} and i_{b} currents (in the a-B reference frame) into a rotating d-q reference frame. The d-q reference frame rotates with the rotor's magnetic field and is aligned such that the d-axis is aligned with the rotor's magnetic field while the q-axis is 90° ahead in the direction of rotation. The currents in the d-q reference frame are represented as the quadrature-axis current (i_{q}) and the direct-axis current (i_{d}). The quadrature-axis current (i_{q}) may affect the torque generated by the motor 505, while the direct-axis current (i_{d}) affects the magnetic flux generated by the rotor's magnets.

Accordingly, in various implementations, the sensor(s) 525 may monitor currents flowing through the windings of the motor 505 and/or the stator current flowing through the stator windings of the motor 505, and the controller 500 may transform the current measurements (e.g., using Clarke and Park transformations) to compute the quadrature-axis current (i_{q}) and/or a direct-axis current (i_{d}) of motor 505.

At block 804, the controller 500 monitors a speed value. In various implementations, controller 500 monitors a rotational speed (ω) of the motor 505 as measured by the sensor(s) 525. For example, the sensor(s) 525 may include positions sensors, such as encoders and/or Hall effect sensors, and the controller 500 monitors the rotational speed (ω) of the motor 505 based on measurements from the position sensors. In some examples, the encoders include incremental encoders, which generate a series of pulses as the motor 505 rotates. The controller 500 counts the pulses over a time interval to determine the rotational speed (ω) of the motor 505. In various implementations, the encoders include absolute encoders, which provide a unique code for each position of the motor 505. The controller 500 monitors the changes in the position of the motor 505 (based on the unique codes) over a time interval to determine the rotational speed (ω) of the motor 505. In some examples, the magnets of the motor 505 pass by the Hall effect sensors as the motor 505 spins. Each time a magnet passes by a Hall effect sensor, the magnetic field changes the voltage across the sensor. The controller 500 monitors the changes in voltages at the sensor(s) 525 (e.g., by monitoring the number of transitions over a time interval) to determine the rotational speed (ω) of the motor 505.

At block 806, the controller 500 computes an effort based on the monitored current value (i) and the monitored rotational speed (ω) of the motor 505. In various implementations, the controller 500 computes the effort by multiplying the monitored current value (i) and the monitored rotational speed (ω), for example, according to equation (6) below:

$$Effort = i \cdot ω \qquad ( 6 )$$

In some examples, the controller 500 computes the torque (τ) of the motor 505 as a function of the monitored current value (i) and a known torque constant (k_{τ}) of the motor 505, for example, according to equation (7) below:

$$τ = {k}_{τ} \cdot i \qquad ( 7 )$$

The controller 500 may compute the effort of the motor 505 as the mechanical power (P) output by the motor 505 as a function of the computed torque (τ) and the monitored rotational speed of the motor (ω), for example, according to equation (8) below:

$$P = τ \cdot ω \qquad ( 8 )$$

The controller 500 may compare the computed effort of the motor 505 to a threshold at decision block 808. In various implementations, the threshold is a pre-set fixed value. In some examples, the threshold is a value set by the user. In various implementations, the threshold is adjusted according to known algorithms. In some examples, the threshold is adjusted according to operating modes of the power tool 10 and/or control modes of the motor 505. In response to the controller 500 determining that the computed effort of the motor 505 does not exceed the threshold (“NO” at decision block 808), the controller 500 continues monitoring the current value at block 802. In response to the controller 500 determining that the computed effort of the motor 505 exceeds the threshold (“YES” at decision block 808), the controller 500 enables effort limiting for the motor 505 at block 810.

In various implementations, the controller 500 enables effort limiting by reducing the duty cycle of the motor 505. In some examples, the controller 500 enables effort limiting by reducing the pulse-width of the PWM signal used to control the motor 505. In various implementations, the controller enables effort limiting by reducing the conduction band of the signal used to drive the motor 505. In some examples, the controller 500 enables effort limiting by adjusting the advance angle of the control signal used to control the motor 505.

In various implementations, the controller 500 controls the motor 505 according to block commutation and/or field oriented control (“FOC”). In some examples, the controller 500 controls the motor 505 according to sensorless FOC. In various implementations, the controller 500 enables effort limiting by reducing the duty cycle, the magnitude of the voltage applied to the motor 505, and/or the amplitude of the current provided to the motor 505. In some examples, the controller 500 enables effort limiting by controlling (e.g., reducing) the quadrature-axis current (i_{q}) and/or the direct-axis current (i_{d}) components of the stator current of the motor 505.

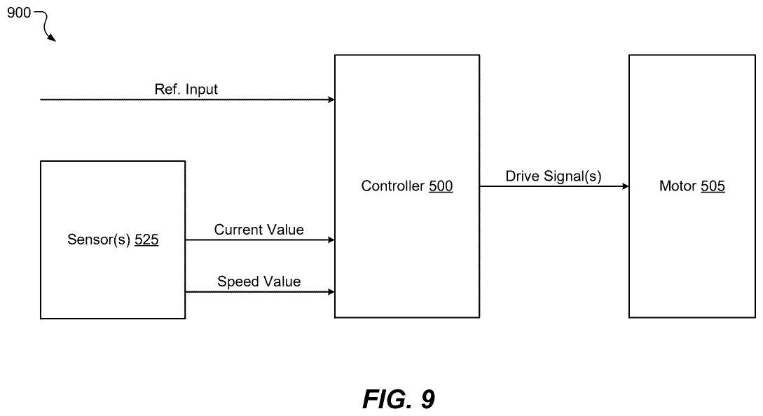

FIG. 9 is a block diagram illustrating a control loop 900 that may be used to implement control schemes according to the process 800 of FIG. 8. In various implementations, the control loop 900 may be implemented by the controller 500. As illustrated in FIG. 9, the controller 500 may receive a reference input in the form of a commanded speed, a commanded torque, etc. (e.g., representing a desired operational state of the motor 505) from the trigger switch 515, the user input 535, etc. The controller 500 may also receive a current value of a current provided to and/or at the motor 505 and/or a speed value of the motor 505. In various implementations, instead of receiving the speed value from the sensor(s) 525, the controller 500 computes the speed value using a sensorless algorithm.

The controller 500 drives the motor 505 according to the reference input (for example, by controlling drive signal(s) output to the motor 505. In various implementations, the motor 505 is a DC motor, and the drive signal(s) include PWM signals that control the average voltage (e.g., power) applied to the motor 505 by rapidly switching the voltage on and off. In some examples, the motor 505 is an AC motor and the drive signal(s) include adjustments of the amplitude, frequency, and/or phase of the AC signal provided to the motor 505. As the motor 505 is driven, the controller 500 computes an effort according to the current value and the speed value (e.g., by multiplying the current value and the speed value) and determines whether the effort exceeds a threshold. In response to determining that the effort exceeds the threshold, the controller 500 reduces the effort of the motor 505 (e.g., by reducing the duty cycle of the PWM signal, reducing the voltage of the AC signal, adjusting the frequency of the AC signal, reducing the current of the drive signal(s), applying field weakening, etc.).

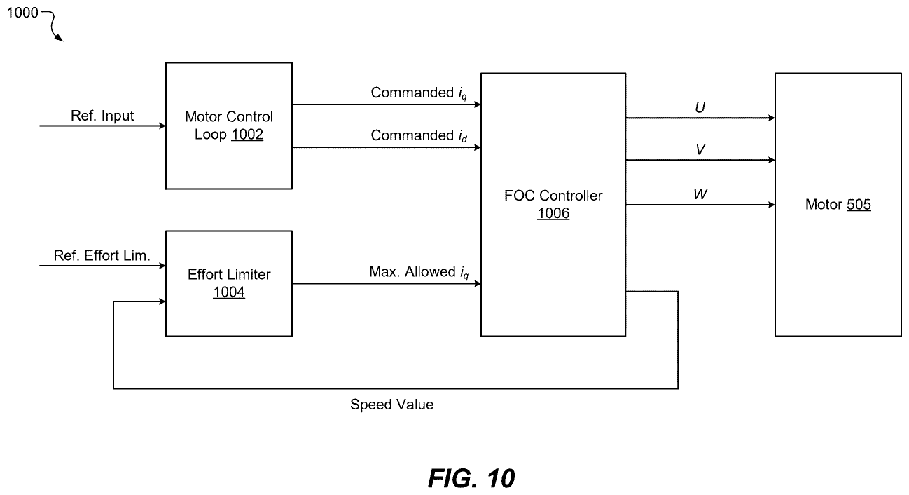

FIG. 10 is a block diagram illustrating a control loop 1000 that may be used to implement control schemes according to the process 800 of FIG. 8. In various implementations, the control loop 1000 may be implemented by the controller 500. As illustrated in FIG. 10, the control loop 1000 may include a motor control loop 1002, an effort limiter 1004, and/or an FOC controller 1006. The motor control loop 1002 may receive a reference input in the form of a commanded speed, a commanded torque, etc. (e.g., representing a desired operational state of the motor 505) from the trigger switch 515, the user input 535, etc. The motor control loop 1002 may be a higher-level motor control loop that calculates the optimal current components that need to be provided to the motor 505 to achieve the commanded state. For example, the motor control loop 1002 may calculate and output a commanded quadrature-axis current (i_{q}) and/or a commanded direct-axis current (i_{d}) to the FOC controller 1006.

The effort limiter 1004 may receive a reference effort limit (for example, from the user input 535). In various implementations, the effort limiter 1004 may be pre-programmed with the reference effort limit. In some examples, the reference effort limit may be a power limit. The effort limiter 1004 may receive a speed value (e.g., from the FOC controller 1006 and/or the sensor(s) 525) indicating the monitored rotational speed (ω) of the motor 505 and compute a maximum allowed quadrature-axis current (i_{q}) based on the reference effort limit value and the speed value. For example, the effort limiter 1004 may divide the reference effort limit value by the speed value to determine the maximum allowed quadrature-axis current (i_{q}). The effort limiter 1004 may output the maximum allowed quadrature-axis current (i_{q}) to the FOC controller 1006.

The FOC controller 1006 may determine whether the commanded quadrature-axis current (i_{q}) received from the motor control loop 1002 exceeds the maximum allowed quadrature-axis current (i_{q}) received from the effort limiter 1004. In response to determining that the commanded quadrature-axis current (i_{q}) exceeds the maximum allowed quadrature-axis current (i_{q}), the FOC controller 1006 sets the commanded quadrature-axis current (i_{q}) to the maximum allowed quadrature-axis current (i_{q}). The FOC controller 1006 then converts the commanded quadrature-axis current (i_{q}) and the commanded direct-axis current (i_{d}) into phase voltages (such as three phase voltages U, V, and W) for the motor 505. In various implementations, the FOC controller 1006 monitors the rotational speed (ω) of the motor 505 via the sensor(s) 525 and outputs the speed value as feedback to the effort limiter 1004. In some examples, the FOC controller 1006 computes the rotational speed (ω) of the motor 505 using a sensorless algorithm.

### EXAMPLES

The following paragraphs provide examples of systems, methods, and devices implemented in accordance with this specification.

Example 1. A power tool comprising: an electric motor; an interface configured to receive a battery pack; and an electronic controller configured to: monitor a current value between the battery pack and the electric motor, monitor a voltage value between the battery pack and the electric motor, compute a power value based on the current value and the voltage value, and reduce, in response to the power value exceeding a threshold, an input power of the electric motor.

Example 2. The power tool of example 1, wherein the current value is at least one of an inverter current value, a motor phase current value, and a battery current value.

Example 3. The power tool of example 1, wherein the voltage value is at least one of an inverter voltage value, a motor phase voltage value, and a battery voltage value.

Example 4. The power tool of example 1, wherein the electronic controller is configured to compute the power value based on the current value, the voltage value, and a duty cycle of the electric motor.

Example 5. The power tool of example 1, wherein the current value is a current value measured during an ON portion of a pulse width modulation signal.

Example 6. The power tool of example 1, wherein the power value is a time-averaged power value.

Example 7. The power tool of example 6, wherein, to compute the power value, the electronic controller is configured to provide the time-averaged power value to a filter.

Example 8. The power tool of example 7, wherein the filter is an infinite-impulse-response filter.

Example 9. The power tool of example 1, wherein the power value is a root mean square value.

Example 10. The power tool of example 1, wherein, to reduce the input power of the electric motor, the electronic controller is configured to reduce a requested pulse-width-modulation (“PWM”) value of the electric motor.

Example 11. The power tool of example 1, wherein the threshold is a first threshold, and wherein the electronic controller is configured to no longer reduce the input power of the electric motor in response to the power value falling below a second threshold, the second threshold lower than the first threshold.

Example 12. The power tool of example 1, further comprising: a spring-mass system driven by the electric motor.

Example 13. The power tool of example 12, wherein the spring-mass system includes a hammer configured to strike an anvil, and a spring configured to bias the hammer toward the anvil.

Example 14. A method of controlling an electric motor of a power tool, the method comprising: monitoring a current value between a battery pack and the electric motor; monitoring a voltage value between the battery pack and the electric motor; computing a power value based on the current value and the voltage value; and reducing, in response to the power value exceeding a threshold, an input power of the electric motor.

Example 15. The method of example 14, wherein the current value is at least one of an inverter current value, a motor phase current value, and a battery current value.

Example 16. The method of example 14, wherein the voltage value is at least one of an inverter voltage value, a motor phase voltage value, and a battery voltage value.

Example 17. The method of example 14, wherein the power value is computed based on the current value, the voltage value, and a duty cycle of the electric motor.

Example 18. The method of example 14, wherein the current value is a current value measured during an ON portion of a pulse width modulation signal.

Example 19. The method of example 14, wherein the power value is a time-averaged power value.

Example 20. The method of example 19, wherein computing the power value includes providing the time-averaged power value to a filter.

Example 21. The method of example 20, wherein the filter is an infinite-impulse-response filter.

Example 22. The method of example 14, wherein the power value is a root mean square value.

Example 23. The method of example 14, wherein reducing the input power of the electric motor includes reducing a requested pulse-width-modulation (PWM) value of the electric motor.

Example 24. The method of example 14, wherein: the threshold is a first threshold; and the method further comprising: stopping the reducing of the input power of the electric motor in response to the power value falling below a second threshold, the second threshold lower than the first threshold.

Example 25. The method of example 14, wherein the electric motor is configured to drive a spring-mass system.

Example 26. The method of example 25, wherein the spring-mass system includes a hammer configured to strike an anvil and a spring configured to bias the hammer toward the anvil.

Example 27. A power tool comprising: an electric motor; and an electronic controller configured to: monitor a current value associated with the electric motor, monitor a speed value associated with the electric motor, compute an effort value based on the current value and the speed value, and reduce an effort of the electric motor in response to the effort value exceeding a threshold.

Example 28. The power tool of example 27, wherein, to compute the effort value, the electronic controller is configured to multiply the current value and the speed value.

Example 29. The power tool of example 27, where, to reduce the effort of the electric motor, the electronic controller is configured to reduce a duty cycle of the electric motor.

Example 30. The power tool of example 27, wherein, to reduce the effort of the electric motor, the electronic controller is configured to reduce a current supplied to the electric motor.

Example 31. The power tool of example 27, wherein, to reduce the effort of the electric motor, the electronic controller is configured to reduce a voltage supplied to the electric motor.

Example 32. The power tool of example 27, wherein, to reduce the effort of the electric motor, the electronic controller is configured to reduce a quadrature-axis current of the electric motor.

Example 33. The power tool of example 27, wherein, to reduce the effort of the electric motor, the electronic controller is configured to: receive a commanded quadrature-axis current; receive a maximum allowed quadrature-axis current; set, in response to the commanded quadrature-axis current exceeding the maximum allowed quadrature-axis current, a value of the commanded quadrature-axis current to the maximum allowed quadrature-axis current; and compute a drive signal for the electric motor based on the value of the commanded quadrature-axis current.

Example 34. The power tool of example 27, wherein, to monitor the speed value of the electric motor, the electronic controller is configured to monitor signals from one or more sensors at the electric motor.

Example 35. The power tool of example 27, wherein, to monitor the speed value, the electronic controller is configured to compute a rotational speed of the electric motor using a sensorless algorithm.

Example 36. The power tool of example 27, wherein the speed value is a rotational speed of the electric motor.

Example 37. A method of controlling an electric motor of a power tool, the method comprising: monitoring a current value associated with the electric motor; monitoring a speed value associated with the electric motor; computing an effort value based on the current value and the speed value; and reducing an effort of the electric motor in response to the effort value exceeding a threshold.

Example 38. The method of example 37, wherein computing the effort value based on the current value and the speed value includes multiplying the current value and the speed value.

Example 39. The method of example 37, wherein reducing the effort of the electric motor includes reducing a duty cycle of the electric motor.

Example 40. The method of example 37, wherein reducing the effort of the electric motor includes reducing a current supplied to the electric motor.

Example 41. The method of example 37, wherein reducing the effort of the electric motor includes reducing a voltage supplied to the electric motor.

Example 42. The method of example 37, wherein reducing the effort of the electric motor includes reducing a quadrature-axis current of the electric motor.

Example 43. The method of example 37, wherein reducing the effort of the electric motor includes: receiving a commanded quadrature-axis current; receiving a maximum allowed quadrature-axis current; setting, in response to the commanded quadrature-axis current exceeding the maximum allowed quadrature-axis current, a value of the commanded quadrature-axis current to the maximum allowed quadrature-axis current; and computing a drive signal for the electric motor based on the value of the commanded quadrature-axis current.

Example 44. The method of example 37, wherein monitoring the speed value associated with the electric motor includes monitoring signals from one or more sensors at the electric motor.

Example 45. The method of example 37, wherein monitoring the speed value associated with the electric motor includes computing a rotational speed of the electric motor using a sensorless algorithm.

Example 46. The method of example 37, wherein the speed value is a rotational speed of the electric motor.

Example 47. A power tool comprising: an electric motor, an interface configured to receive a battery pack, and an electronic controller configured to: monitor a current value between the battery pack and the electric motor, monitor a voltage value between the battery pack and the electric motor, compute a power value based on the current value and the voltage value, and reduce, in response to the power value reaching a threshold value, an input power of the electric motor.

Thus, embodiments described herein provide, among other things, a power tool including power limiting motor control. Various features and advantages are set forth in the following claims.

What is claimed is:

1. A power tool comprising:
an electric motor;
an interface configured to receive a battery pack; and
an electronic controller configured to:
monitor a current value between the battery pack and the electric motor,
monitor a voltage value between the battery pack and the electric motor,
compute a power value based on the current value and the voltage value, and
reduce, in response to the power value exceeding a threshold, an input power of the electric motor.

2. The power tool of claim 1, wherein the current value is at least one of an inverter current value, a motor phase current value, and a battery current value.

3. The power tool of claim 1, wherein the voltage value is at least one of an inverter voltage value, a motor phase voltage value, and a battery voltage value.

4. The power tool of claim 1, wherein the electronic controller is configured to compute the power value based on the current value, the voltage value, and a duty cycle of the electric motor.

5. The power tool of claim 1, wherein the current value is a current value measured during an ON portion of a pulse width modulation signal.

6. The power tool of claim 1, wherein the power value is a time-averaged power value.

7. The power tool of claim 6, wherein, to compute the power value, the electronic controller is configured to provide the time-averaged power value to a filter.

8. The power tool of claim 7, wherein the filter is an infinite-impulse-response filter.

9. The power tool of claim 1, wherein, to reduce the input power of the electric motor, the electronic controller is configured to reduce a requested pulse-width-modulation (“PWM”) value of the electric motor.

10. The power tool of claim 1, wherein the threshold is a first threshold, and wherein the electronic controller is configured to no longer reduce the input power of the electric motor in response to the power value falling below a second threshold, the second threshold lower than the first threshold.

11. A method of controlling an electric motor of a power tool, the method comprising:
monitoring a current value between a battery pack and the electric motor;
monitoring a voltage value between the battery pack and the electric motor;
computing a power value based on the current value and the voltage value; and
reducing, in response to the power value exceeding a threshold, an input power of the electric motor.

12. The method of claim 11, wherein the current value is at least one of an inverter current value, a motor phase current value, and a battery current value.

13. The method of claim 11, wherein the voltage value is at least one of an inverter voltage value, a motor phase voltage value, and a battery voltage value.

14. The method of claim 11, wherein the power value is computed based on the current value, the voltage value, and a duty cycle of the electric motor.

15. The method of claim 11, wherein the current value is a current value measured during an ON portion of a pulse width modulation signal.

16. The method of claim 11, wherein the power value is a time-averaged power value.

17. The method of claim 16, wherein computing the power value includes providing the time-averaged power value to a filter.

18. The method of claim 11, wherein reducing the input power of the electric motor includes reducing a requested pulse-width-modulation (PWM) value of the electric motor.

19. The method of claim 11, wherein:
the threshold is a first threshold; and
the method further comprising:
stopping the reducing of the input power of the electric motor in response to the power value falling below a second threshold, the second threshold lower than the first threshold.

20. A power tool comprising:
an electric motor;
an interface configured to receive a battery pack; and
an electronic controller configured to:
monitor a current value between the battery pack and the electric motor,
monitor a voltage value between the battery pack and the electric motor,
compute a power value based on the current value and the voltage value, and
reduce, in response to the power value reaching a threshold value, an input power of the electric motor.
